(19) United States
(12) Patent Application Publication
(10) Pub. No.: US 2008/0030949 A1
(43) Pub. Date: Feb. 7, 2008

(54) FLUID-PROVIDING MODULE AND ELECTRONIC DEVICE USING THE SAME

(75) Inventor: Ming-Yang Hsiao, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: ASUSTEK COMPUTER INC., Taipei (TW)

(21) Appl. No.: 11/830,859

(22) Filed: Jul. 31, 2007

(30) Foreign Application Priority Data
Aug. 1, 2006 (TW) 95128087

(51) Int. Cl. H05K 7/20

(52) U.S. Cl. 361/689

(57) ABSTRACT

A fluid-providing module including a housing and a fan is provided. The housing includes a first inlet and a space connected to the first inlet. The space includes a first channel and a second channel such that one is stacked on top of the other. The first channel includes a first outlet and the second channel includes a second outlet. The fan is disposed in the space for moving the fluid and discharging the fluid from the housing through the first outlet and the second outlet. Consequently, the fluid-providing module can discharge the fluid in multiple directions. In addition, an electronic device using the fluid-providing module is also provided.

### CROSS-REFERENCE TO RELATED APPLICATION

This application claims the priority benefit of Taiwan application serial no. 95128087, filed Aug. 1, 2006. All disclosure of the Taiwan application is incorporated herein by reference.

### BACKGROUND OF THE INVENTION

1. Field of the Invention

The present invention relates to a fluid-providing module, and more particularly, to a fluid-providing module that can be used inside an electronic device for dissipating heat produced by the electronic device.

2. Description of Related Art

With the rapid advance in electronic technologies, many types of electronic devices are so widely adopted that living without them is unimaginable. One common characteristic of these electronic devices is that they all use electric power as the main energy source. As a result, their operations are usually accompanied by the generation of a significant quantity of heat energy. If the heat is not efficiently dissipated, the electronic device may produce operational errors or temporarily fail. In some cases, the electronic device may receive lasting damages.

For example, as the processing speed of a computer continues to increase gradually, there is a need for higher heat dissipation efficiency inside the computer. In other words, the capacity for dissipating heat from the electronic devices inside the computer is increasingly important. Besides the cooling fan installed inside the computer, other electronic components inside the computer host such as the power supply, the central processing unit (CPU), the graphic processing unit (GPU) and the chipset also generate heat and thus increase surrounding temperature. All these components need additional heat sink to lower their temperature during high-speed operation so that the computer can operate more smoothly.

To achieve remote heat exchange, an additional heat pipe connected to a heat sink at a heat source may be provided so that heat can be transferred from the heat sink at the heat source to a remote heat sink. Furthermore, a fluid-providing module can be used to move fluid around the heat sink to perform active heat dissipation, thereby increasing the heat dissipation efficiency of the heat sink.

However, the fluid-providing module having an inlet and outlet set in a direction perpendicular to each other normally has only a single outlet so that the fluid provided by the fluid-providing module can only perform heat dissipation on a single heat sink. Hence, a single fluid-providing module cannot supply fluid to two or more heat sinks simultaneously. Yet, installing an additional fluid-providing module is often constrained by spatial limitation, which is quite obvious for a notebook computer. Therefore, the heat dissipation capacity and efficiency of the conventional single-outlet fluid-providing module are severely limited.

### SUMMARY OF THE INVENTION

Accordingly, one objective of the present invention is to provide a fluid-providing module capable of discharging fluid in multiple directions.

Another objective of the present invention is to provide an electronic device having a fluid-providing module capable of discharging fluid in multiple directions.

In accordance with the above or other objective of the present invention, the present invention provides a fluid-providing module including a housing and a fan. The housing includes a first inlet and a space connected to the first inlet. The space includes a first channel and a second channel such that one is stacked on top of the other. The first channel includes a first outlet and the second channel includes a second outlet. The fan is disposed in the space for moving the fluid and discharging the fluid from the housing through the first outlet and the second outlet.

In accordance with the above or other objective of the present invention, the present invention provides an electronic device includes a casing, a circuit board and the foregoing fluid-providing module. The circuit board and the fluid-providing module are disposed inside the casing.

In one embodiment of the present invention, the direction of fluid discharged from the first outlet is different from the direction of fluid discharged from the second outlet.

In one embodiment of the present invention, the direction of fluid drawn into the first inlet is substantially perpendicular to the direction of fluid discharged from the first outlet.

In one embodiment of the present invention, the direction of fluid drawn into the first inlet is substantially perpendicular to the directions of fluid discharged from the first outlet and the second outlet.

In one embodiment of the present invention, the housing has a second inlet connected to the space.

In one embodiment of the present invention, the direction of fluid drawn into the second inlet is substantially perpendicular to the direction of fluid discharged from the first outlet. Furthermore, the direction of fluid drawn into the second inlet is substantially perpendicular to the direction of fluid discharged from the second outlet.

In one embodiment of the present invention, the housing includes a first cover, a first frame, a second frame and a second cover sequentially stacked one after the other. The first cover constitutes the first inlet, the first frame constitutes the first channel, and the second frame constitutes the second channel.

In one embodiment of the present invention, the second cover has a second inlet connected to the space.

In one embodiment of the present invention, the fan includes a blade set and a motor for rotating the blade set.

In the present invention, a design with multiple channels and outlets inside the housing of the fluid-providing module is deployed so that the fluid propelled by the fan is split in different directions through the channels and discharged through the outlets. Therefore, the same fluid-providing module can be used to dissipate the heat from two or more heat sources or heat sinks and the fluid discharged from the same fluid-providing module is able to serve a larger heat dissipation area.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a perspective view of a fluid-providing module according to one embodiment of the present invention.

FIG. 2 is an exploded view showing the components of the fluid-providing module in FIG. 1.

FIG. 3 is a top view showing the first channel and the second channel of the fluid-providing module in FIG. 1.

FIG. 4 shows one application of the fluid-providing module in FIG. 1 in an electronic device.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

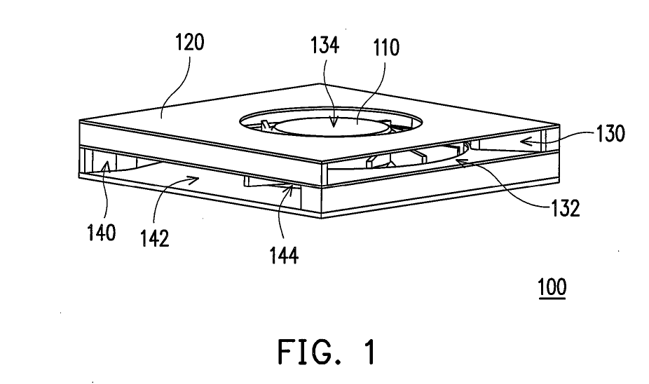

FIG. 1 is a perspective view of a fluid-providing module according to one embodiment of the present invention. As shown in FIG. 1, the fluid-providing module 100 in the present embodiment includes a fan 110 and a housing 120. The housing 120 has a space and the fan 110 is disposed in the space. The space further includes a first channel 130 and a second channel 140 such that one is stacked on top of the other. The first channel 130 has a first outlet 132 and the second channel 140 has a second outlet 142. In addition, there is a first inlet 134 on the upper side of the housing 120 and the first inlet 134 is connected to the space. To increase the quantity of input fluid, the lower side of the housing 120 opposite the first inlet 134 may include a second inlet 144. The second inlet 144 is also connected to the space.

As shown in FIG. 1, the direction of fluid drawn into the first inlet 134 is substantially perpendicular to the directions of fluid discharged from the first outlet 132 and the second outlet 142, and the direction of fluid drawn into the second inlet 144 is substantially perpendicular to the directions of fluid discharged from the first outlet 132 and the second outlet 142. In addition, the direction of fluid discharged from the first outlet 132 is different from the direction of fluid discharged from the second outlet 142. For example, the two outlets are at right angle to each other or facing opposite directions.

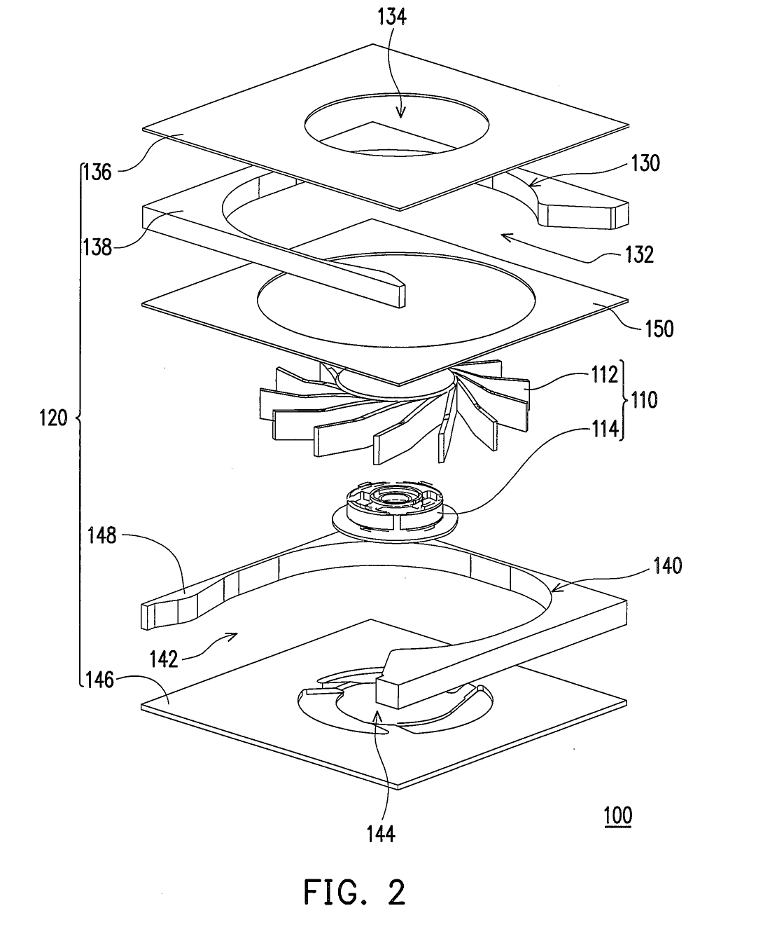

FIG. 2 is an exploded view showing the components of the fluid-providing module in FIG. 1. As shown in FIG. 2, the fan 110 in the present embodiment includes a blade set 112 and a motor 114. The housing 120 includes a first cover 136, a first frame 138, a second frame 148 and a second cover 146 that are sequentially stacked one over the other. The first cover 136 constitutes the first inlet 134, the first frame 138 underneath the first cover 136 constitutes the first channel 130, the second frame 148 underneath the first frame 138 constitutes the second channel 140, and the second cover 146 underneath the second frame 148 constitutes the second inlet 144. Furthermore, the housing 120 further includes a channel partition 150 that separates the upper first channel 130 from the lower second channel 140.

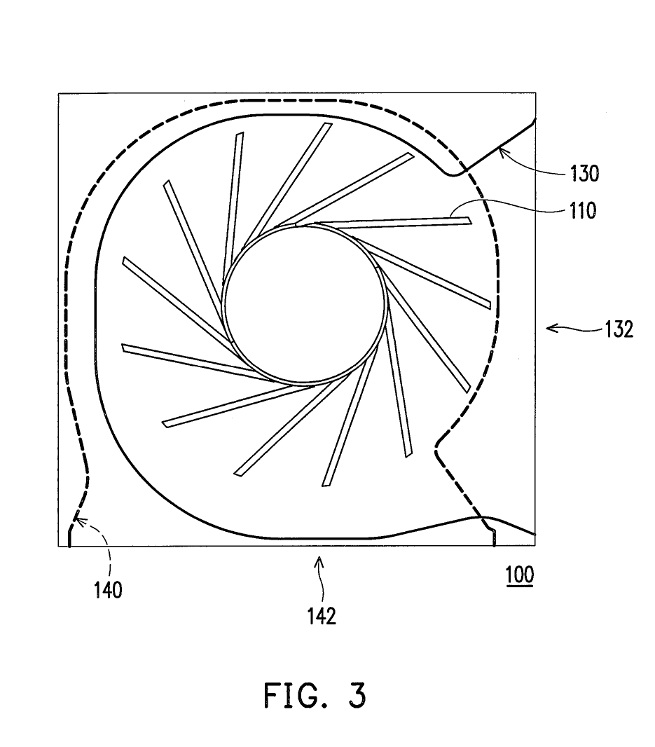

FIG. 3 is a top view showing the first channel and the second channel of the fluid-providing module in FIG. 1. As shown in FIGS. 1 and 3, the first channel 130 of the fluid-providing module 100 in the present embodiment is stacked on top of the second channel 140. Moreover, the first channel 130 and the second channel 140 surround the fan 110. The fluid drawn by the fan 110 flows into the space through the first inlet 134 and the second inlet 144 and then is discharged from the housing 120 through the first outlet 132 and the second outlet 142 via the first channel 130 and the second channel 140 respectively. In the present embodiment, the housing 120 of the fluid-providing module 100 includes two channels and two outlets. In other embodiments, the housing of the fluid-providing module may include more than two channels and outlets.

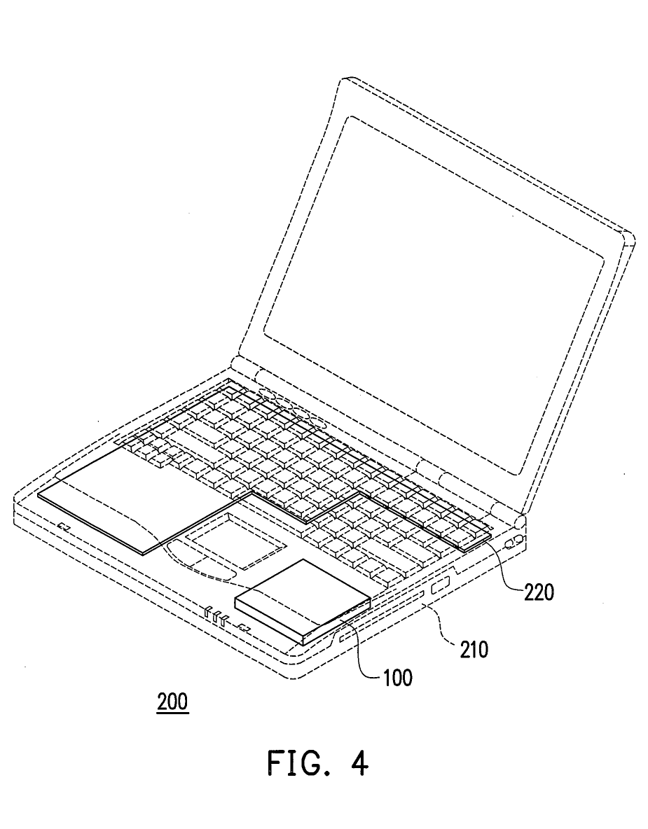

FIG. 4 shows one application of the fluid-providing module in FIG. 1 in an electronic device. As shown in FIG. 4, the electronic device 200 is a notebook computer or other type of electronic device, for example. The electronic device 200 includes a casing 210, a circuit board 220 and the fluid-providing module 100 shown in FIG. 1. The circuit board 220 and the fluid-providing module 100 are disposed inside the casing 210. The fluid-proving module 100 is set up inside the casing 210 of the electronic device 200 to provide the fluid necessary for cooling. Because the fluid-providing module 100 has multiple channels and outlets for providing a stream of fluid in different directions, fluid discharged from the fluid-providing module 100 can be simultaneously directed to a number of heat sinks inside the electronic device 200 in order to cool them down.

In summary, the fluid-providing module and the electronic device using the same have at least the following advantages:

1. Because the fluid-providing module has a plurality of channels and outputs, the fluid-providing module is able to simultaneously discharge the fluid in different directions.

2. Because the fluid-providing module discharges the fluid in different directions, the fluid flowing in multiple directions may be channeled to different heat sinks, thereby increasing the overall heat dissipation area.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fluid-providing module, comprising:
a housing, having a first inlet and a space connected to the first inlet, wherein the space includes a first channel and a second channel such that one stacks over the other, the first channel has a first outlet and the second channel has a second outlet; and
a fan, disposed in the space for moving fluid and discharging the fluid from the housing through the first outlet and the second outlet.

2. The fluid-providing module of claim 1, wherein the direction of fluid discharged from the first outlet is different from the direction of fluid discharged from the second outlet.

3. The fluid-providing module of claim 1, wherein the direction of fluid drawn into the first inlet is substantially perpendicular to the direction of fluid discharged from the first outlet.

4. The fluid-providing module of claim 1, wherein the direction of fluid drawn into the first inlet is substantially perpendicular to the directions of fluid discharged from the first outlet and the second outlet.

5. The fluid-providing module of claim 1, wherein the housing has a second inlet connected to the space.

6. The fluid-providing module of claim 5, wherein the direction of fluid drawn into the second inlet is substantially perpendicular to the direction of fluid discharged from the first outlet.

7. The fluid-providing module of claim 5, wherein the direction of fluid drawn into the second inlet is substantially perpendicular to the direction of fluid discharged from the second outlet.

8. The fluid-providing module of claim 1, wherein the housing comprises a first cover, a first frame, a second frame and a second cover sequentially stacked one over the other such that the first cover constitutes the first inlet, the first frame constitutes the first channel and the second frame constitutes the second channel.

9. The fluid-providing module of claim 8, wherein the second cover has a second inlet connected to the space.

10. The fluid-providing module of claim 1, wherein the fan comprises a blade set and a motor for rotating the blade set.

11. An electronic device, comprising:
a casing;
a circuit board, disposed inside the casing; and
a fluid-providing module, having:
a housing, disposed inside the casing, having a first inlet and a space connected to the first inlet, wherein the space includes a first channel and a second channel such that one stacks over the other, the first channel has a first outlet and the second channel has a second outlet; and
a fan, disposed in the space for moving fluid and discharging the fluid from the housing through the first outlet and the second outlet.

12. The electronic device of claim 11, wherein the direction of fluid discharged from the first outlet is different from the direction of fluid discharged from the second outlet.

13. The electronic device of claim 11, wherein the direction of fluid drawn into the first inlet is substantially perpendicular to the direction of fluid discharged from the first outlet.

14. The electronic device of claim 11, wherein the direction of fluid drawn into the first inlet is substantially perpendicular to the directions of fluid discharged from the first outlet and the second outlet.

15. The electronic device of claim 11, wherein the housing has a second inlet connected to the space.

16. The electronic device of claim 15, wherein the direction of fluid drawn into the second inlet is substantially perpendicular to the direction of fluid discharged from the first outlet.

17. The electronic device of claim 15, wherein the direction of fluid drawn into the second inlet is substantially perpendicular to the direction of fluid discharged from the second outlet.

18. The electronic device of claim 11, wherein the housing comprises a first cover, a first frame, a second frame and a second cover sequentially stacked one over the other such that the first cover constitutes the first inlet, the first frame constitutes the first channel and the second frame constitutes the second channel.

19. The electronic device of claim 18, wherein the second cover has a second inlet connected to the space.

20. The electronic device of claim 11, wherein the fan comprises a blade set and a motor for rotating the blade set.
